(19) United States
(12) Patent Application Publication
(10) Pub. No.: US 2010/0277853 A1
(43) Pub. Date: Nov. 4, 2010

(54) Waterproof Structure in a Tank

(76) Inventors: Chen-Fu TSAI, Taichung City (TW); Chien-Hua Hu, Taichung City (TW)

Correspondence Address: Wang Law Firm, Inc., 4989 Peachtree Parkway,, Suite 200, Norcross, GA, 30092, US

(21) Appl. No.: 12/238,919

(22) Filed: Sep. 26, 2008

(51) Int. Cl. H05K 5/00

(52) U.S. Cl. 361/679.01

(57) ABSTRACT

A waterproof structure in a tank. The circuit board required for discharge machining in the tank is disposed outside the tank. The inner wall of the tank is provided with a waterproof component with a downward opening. The circuit board along with other elements is connected to an electrode contact disposed in the waterproof component. When the machining liquid is full, the air pressure in the air storage space of the waterproof component balances with the liquid pressure at the opening. This prevents the machining liquid from spilling onto the electrode contact and resulting in the bypassing circuit effect. Moreover, the waterproof component can be used at the electrode contact of each base of the conductive platform, providing the same protection.

### BACKGROUND OF THE INVENTION

1. Field of Invention

The invention relates to a waterproof structure in a tank and, in particular, to a device that provides waterproof protection for the electrode connectors in a line cutter.

2. Related Art

Please refer to FIG. 8. The conventional waterproof structure 61 has an electrode and a circuit board (not shown). The waterproof structure 61 is disposed inside the tank of a line cutter. The power of the discharge arm and support platform of the line cutter can be provided using a wire 62 from the electrode.

A waterproof sleeve 63 made of plastic or rubber is disposed between the wires 62 and the waterproof structure 61. Afterwards, waterproof glue 64 is used to seal between the waterproof sleeve 63, the wire 62, and the waterproof structure 61.

Before line cutting, a certain amount of machining fluid has to be stored in the tank for performing the job. In this case, the waterproof structure 61 is immersed in the machining liquid.

However, after long-time use, the waterproof sleeve 63 is likely to harden and therefore break or deform to produce cracks. If this happens, the machining liquid will permeate into the waterproof structure 61, damaging the internal electronic elements. Alternatively, the waterproof glue 64 deteriorates to also produce cracks at the sealed places. This also results in the problem of the machining liquid seeping and electronic element failures.

Besides, the waterproof structure 61 is disposed in a tank. Therefore, it takes up much of the space inside the tank. This causes difficulties in the tank design and subsequent maintenance. When there is imperfect electrical contact between the wire and the circuit board, the waterproof structure 61 has to be disassembled for replacement or maintenance. This is extremely inconvenient.

### SUMMARY OF THE INVENTION

An objective of the invention is to solve the above-mentioned problem by providing a waterproof structure in a tank. The circuit board is disposed outside the tank, and the electrode contact in electrical connection with the circuit board is disposed on the inner wall of the tank. A waterproof component with a downward opening is used to provide waterproof protection on the electrode contact. When the machining liquid is full, the air pressure in the air storage space in the waterproof component and the liquid pressure at the opening thereof are balanced. This pressure balance prevents the machining liquid from touching and damaging the electrode contact.

Another objective of the invention is to provide a waterproof component at the electrode contact of each base of a conductive platform. This prevents the electrode contacts from experiencing the bypass effect.

A further objective of the invention is to reduce the occupied space in the tank by disposing the circuit board and other elements outside the tank and the electrode contact on the inner wall of the tank.

Yet another objective of the invention is to dispose the circuit board and other elements on the outer wall of the tank, making maintenance easier and preventing the circuit board from being damaged by the machining liquid.

To achieve the above-mentioned objectives, the invention includes:

a tank for accommodating a liquid;

a plurality of waterproof components, each of which is disposed in the tank and consists of a cover and a bottom, with an air storage space formed in between and having a downward opening, the connection between the cover and the bottom being airtight so that no air can escape; and

a plurality of electronic elements, which are disposed on the bottom of the air storage space;

wherein when the tank is filled with the liquid, the air pressure in the air storage space and the liquid pressure at the opening of the waterproof component are balanced, preventing the liquid from touching the electronic elements.

### BRIEF DESCRIPTION OF THE DRAWINGS

The invention will become more fully understood from the detailed description given herein below illustration only, and thus is not limitative of the present invention, and wherein:

FIG. 1 is a three-dimensional view of the invention;

FIG. 2 is a side view of the waterproof component according to the invention;

FIG. 3 is a magnified three-dimensional view of the disclosed waterproof component;

FIG. 4 is an exploded view of FIG. 3;

FIG. 5 is a schematic view showing that the air pressure in the air storage space and the liquid pressure when the machining liquid fills the tank are balanced, where the electrode contact is at a safe position;

FIG. 6 is a schematic view of the disclosed tank added with a stop board;

FIG. 7 is a schematic view of the disclosed waterproof component whose cover is made or a metal; and

FIG. 8 is a schematic view of the conventional waterproof structure.

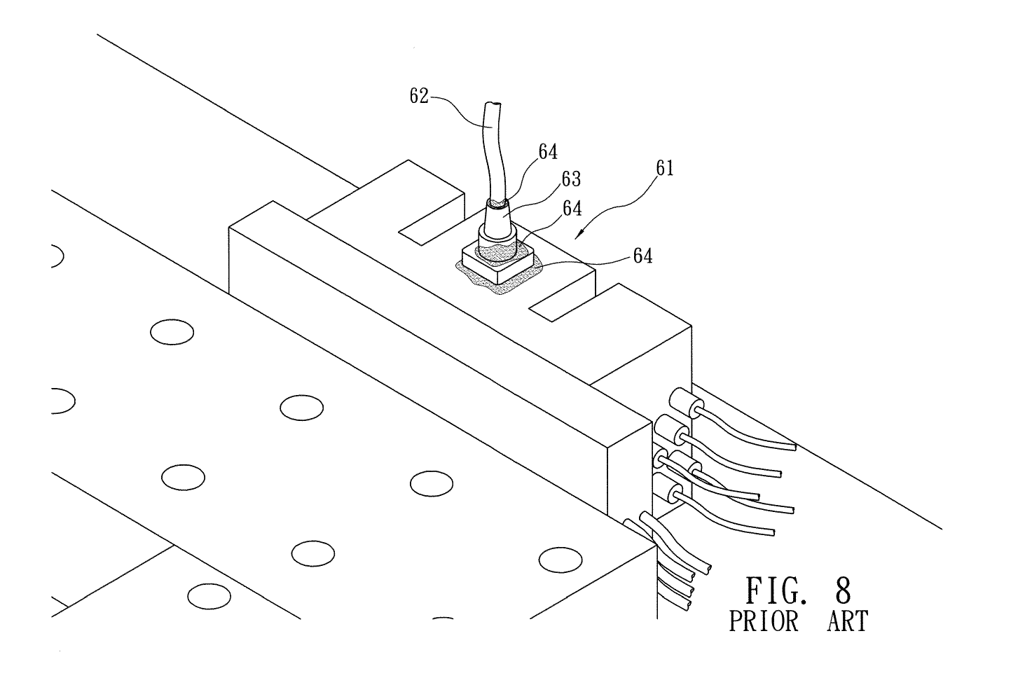

### DETAILED DESCRIPTION OF THE INVENTION

The present invention will be apparent from the following detailed description, which proceeds with reference to the accompanying drawings, wherein the same references relate to the same elements.

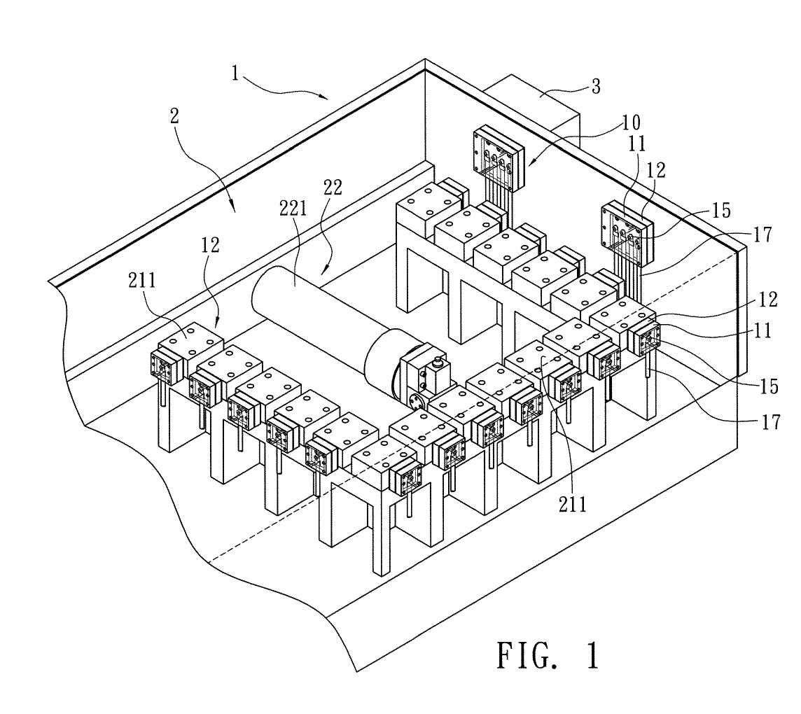

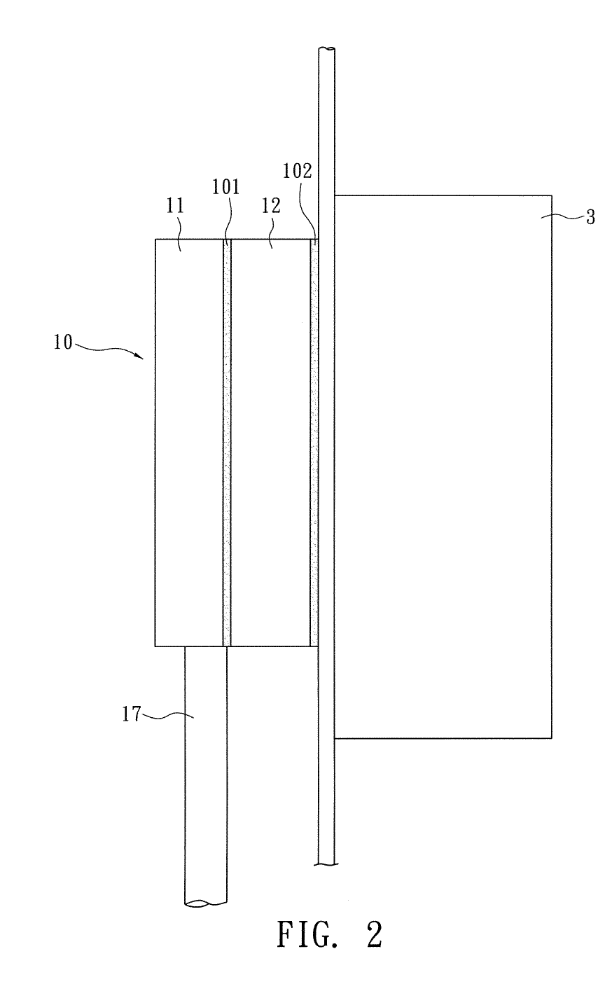

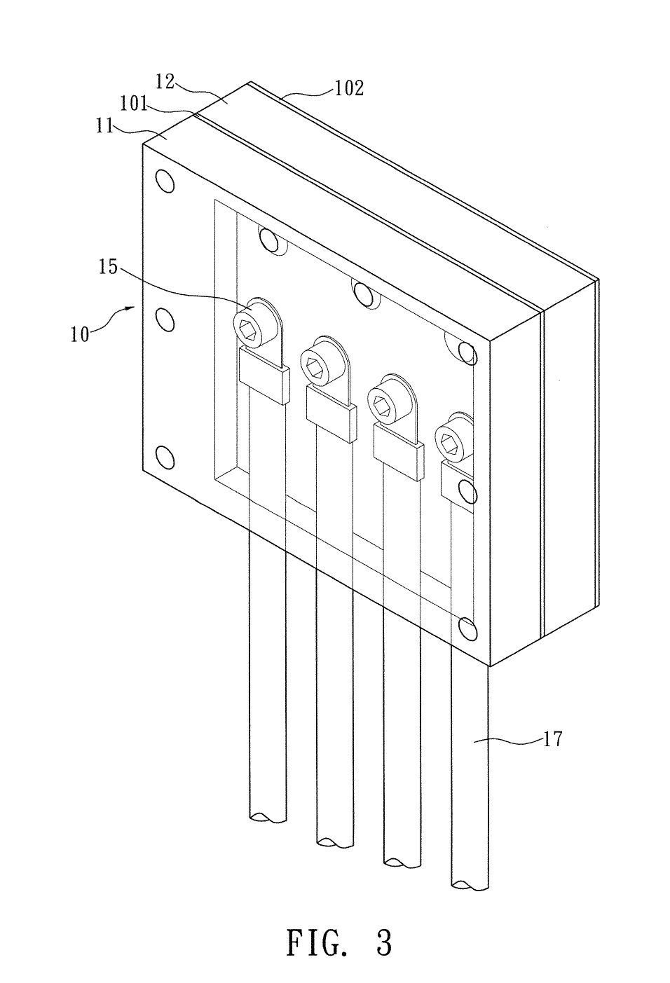

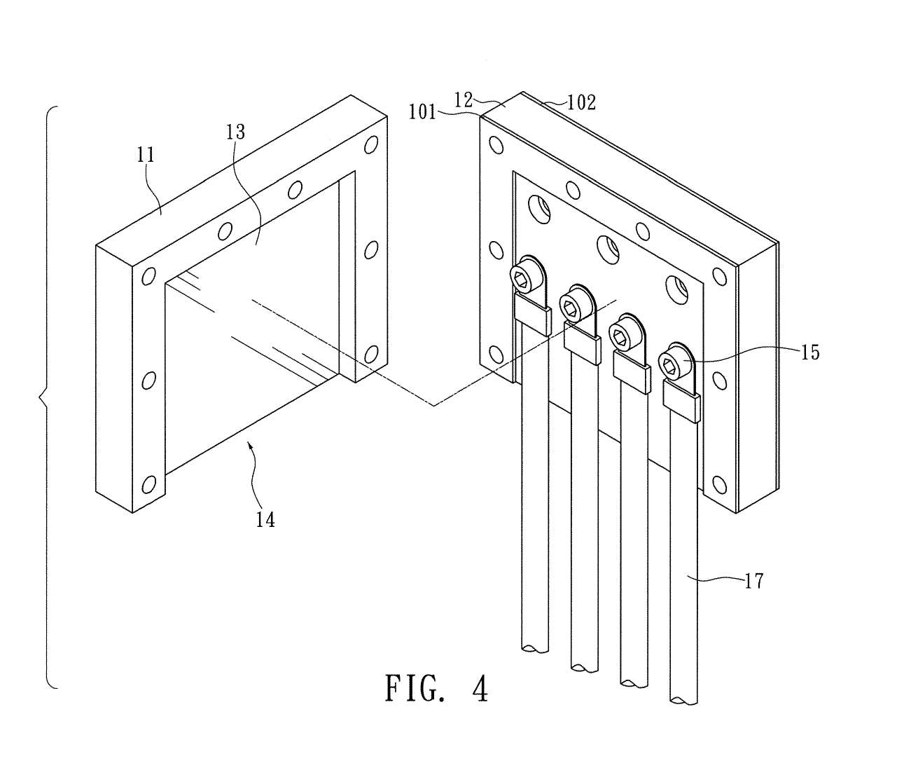

Please refer to FIGS. 1 to 7. They show embodiments of the disclosed structure for the purpose of illustration. The scope and spirit of the invention are not limited to such examples.

Please refer to FIGS. 1 to 4 for the first embodiment of the invention. The tank 1 for accommodating a machining liquid is provided with a plurality of waterproof components 10. Each of the waterproof components 10 includes a cover 11 and a bottom 12. The cover 11 and the bottom 12 combine to form an air storage space 13 that has a downward opening 14. The connections above and on both sides of the cover 11 and the bottom 12 are sealed to be airtight, so that no air can escape from these places. The cover 11 or the bottom 12 can be made of an insulating material such as Bakelite, ceramic, engineering plastic, or glass.

The bottom 12 of the air storage space 13 is disposed with a plurality of electronic elements 15. In this embodiment, the electronic element 15 is an electrode contact. Moreover, the cover 11 is transparent so that the user can check whether the electrode contact inside the air storage space 13 is damaged from outside. The electronic element 15 is electrically connected with a first conductor 16. The first conductor 16 goes through the bottom 12 in an airtight way and has an electrical connection with it. The electronic element 15 is electrically connected with a second conductor 17. The second conductor 17 goes downwards through the opening 14 and has an electrical connection. In this embodiment, the surfaces of the first conductor 16 and the second conductor 17 are covered with an insulating material for insulation.

Besides, several electronic devices 2 are disposed in the tank 1. When there are several waterproof components 10, they are disposed on the outer sides of the electronic devices 2 and on the inner wall of the tank 1. Both ends of the second conductor 17 are electrically connected with the electronic devices 15 in the waterproof components 10 on the outer side of the electronic device 2 and on the inner wall of the tank 1.

In this embodiment, the electronic device 2 includes a conductive platform 21 or a discharge arm 22. The conductive platform 21 consists of several bases 211 that are insulated from one another and disposed in a U shape. The outer wall of each base 211 is formed with the waterproof component 10. The discharge arm 22 includes an upper discharge arm (not shown) and a lower discharge min 221. The outer side of the lower discharge arm 221 is also provided with the waterproof component 10 and the electronic element 15 for power input. The second conductor 17 electrically connects the electronic element 15 in the waterproof component 10 on the inner wall of the tank 1 and the electronic element 15 in the waterproof component 10 at the conductive platform 21 or discharge arm 22, so that the external power can be transmitted via the second conductor 17 to the conductive platform 21 or discharge arm 22.

Moreover, the waterproof component 10 further includes a first soft pad 101 and a second soft pad 102. The cover 11, the first soft pad 101, the bottom 12, and the second soft pad 102 are connected in sequence to achieve the airtight effect. More explicitly, several locking elements (not shown) go through the cover 11, the first soft pad 101, and the bottom 12, followed by locking. Several locking elements (not shown) lock the bottom 12 and the second soft pad 102 on the inner wall of the tank 1 or the outer wall of the electronic device 2.

Besides, a circuit board 3 is disposed on the outer wall of the tank 1 corresponding to the electronic element 15 of the waterproof component 10. The circuit board 3 and the electronic element 15 have an electrical contact going through the wall of the tank 1. Of course, the penetration here is achieved in an airtight means.

Please refer to FIG. 1 again. The waterproof component 10 on the inner wall of the tank 1 has four electronic elements (electrode contacts) 15 on its bottom 12. The waterproof component 10 on the outer wall of each base 211 has one electronic element (electrode contact) 15 on its bottom 12. The electronic elements (electrode contacts) 15 at these two kinds of places are electrically connected in a one-to-one fashion. Therefore, the sizes of the waterproof components 10 at these two kinds of places are slightly different. This is designed to optimize the internal space usage of the tank 1, and does not affect the implement of the invention.

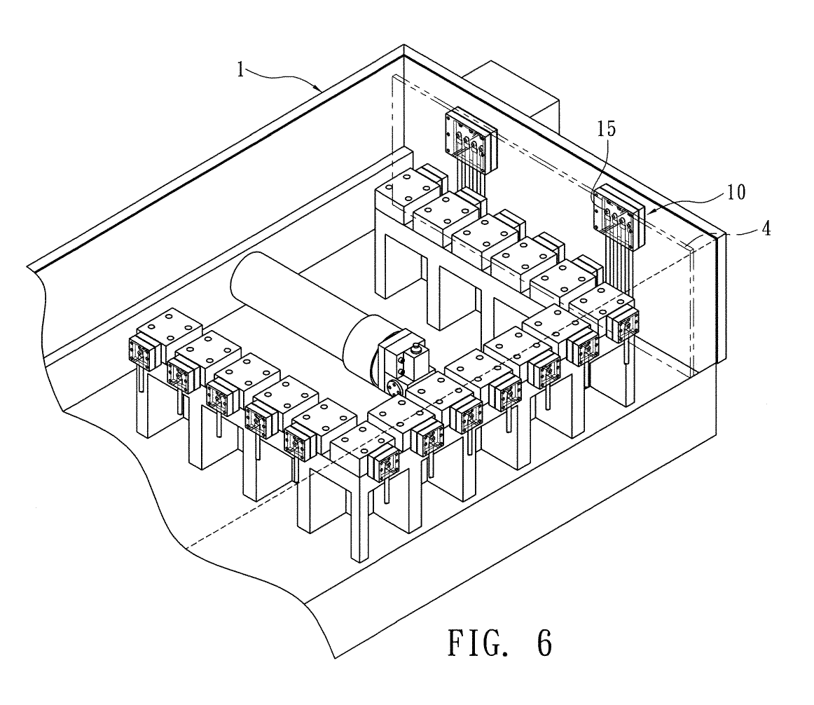

Please refer to FIG. 6. A stop board is disposed next to the waterproof component 10 on the inner wall of the tank 1. The stop board 4 and the waterproof component 10 are disposed symmetrically with respect to the inner wall. During the discharge machining, the machining liquid may produce waves as the upper and lower discharge arms move. Large waves may wet the electronic elements (electrode contacts) 15 on the inner wall of the tank 1. The stop board 4 is provided exactly to prevent this situation from happening.

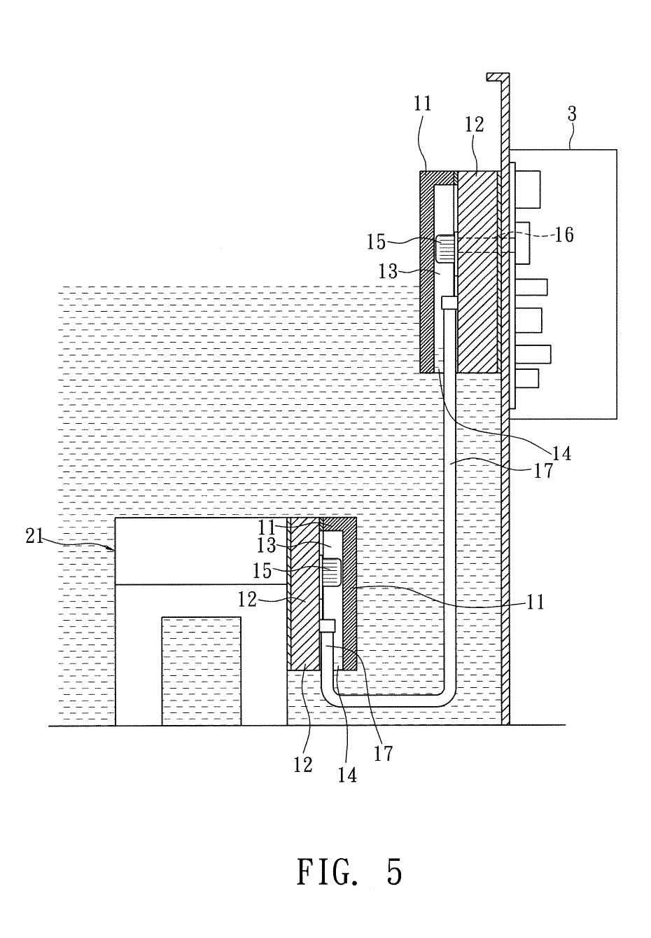

In practice, as shown in FIG. 5, the cover 11 of the waterproof component 10 covers the electronic element (electrode contact) 15, making it located in the air storage space 13. When the machining liquid is filled into the tank 1 and the liquid surface rises to the opening 14 below the waterproof component 10, the liquid compresses the air in the air storage space 13 until the air pressure therein balances the liquid pressure at the opening 14. In this case, the machining liquid does not rise any more, and therefore does not touch the electronic element. Thus, the electronic element (electrode contact) 15 is not wetted and damaged by the machining liquid, avoiding the bypassing circuit effect.

In summary, the invention has the following advantages:

1. When the tank is filled with the machining liquid, the waterproof component enables the air pressure in the air storage space to balance the liquid pressure at the opening below the waterproof component. This prevents the machining liquid from wetting the electrode contact and damaging it. It also prevents the bypassing circuit effect, and thus has better stability.

2. The circuit board in the invention is disposed outside the tank. Only the electrode contact is disposed in the waterproof component. This solves the problem in the prior art that the machining liquid permeates into the waterproof structure to damage the circuit board.

3. Disposing the circuit board outside the tank has the advantages of convenience in maintenance and not occupying space in the tank.

4. When the waterproof component consists of many elements, it has the advantages of a lower cost and ease in assembly.

5. The design of a stop board can effectively prevent the waves of machining liquid from damaging the electrode contact when the machine wobbles.

6. When the cover is made of transparent material, the user can readily observe form outside whether the wire and the electrode contact are electrically connected or whether there is any damage.

7. When the waterproof component consists of many elements, one only needs to take off the cover and other elements after loosening the locking elements in order to lock the wire on the electrode contact. Therefore it solves the problem that the conventional waterproof structure has to be taken apart for replacements, maintenance, and locking.

8. Since the circuit board is disposed outside the tank, it is avoided from being damaged by the machining liquid. It is also convenient for maintenance.

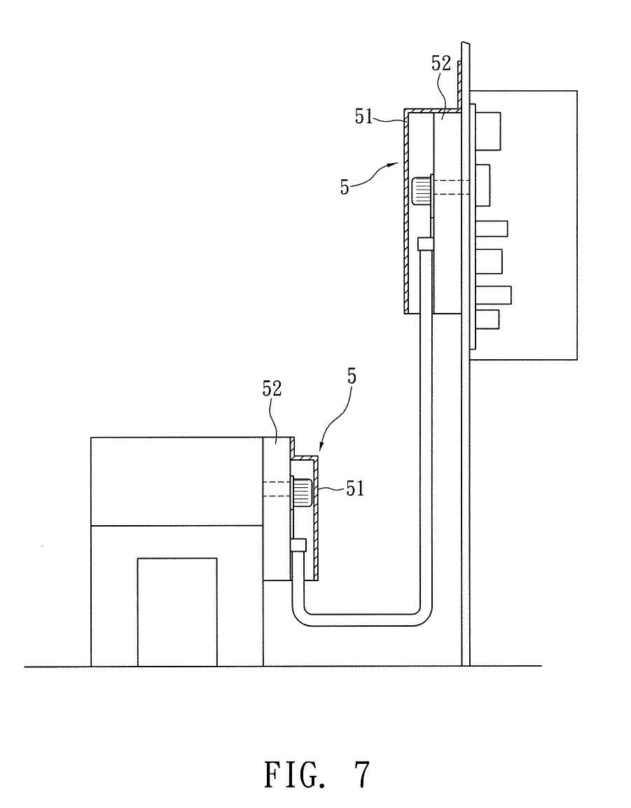

The invention of course has many other embodiments that are different from the above embodiment in minor details. Please refer to FIG. 7, which shows a second embodiment as an example. The cover 51 of the waterproof component 5 is made by bending a metal plate and then disposed on the bottom 52. The connection between them is sealed to achieve the airtight effect. In addition to having the advantages listed for the first embodiment above, this embodiment further has the advantages of quick production and lower cost.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A waterproof structure in a tank, comprising:
a tank for accommodating a liquid;
a plurality of waterproof components disposed in the tank, each of which includes a cover and a bottom together to form an air storage space with a downward opening, the connection between the cover and the bottom being airtight to prevent the air from escaping;
a plurality of electronic elements disposed on the bottom in the air storage space;
wherein when the tank is filled with the liquid, the air pressure in the air storage space balances the liquid pressure at each opening underneath the corresponding waterproof component, preventing the liquid from touching the electronic elements.

2. The waterproof structure in a tank of claim 1, wherein the electronic element is electrically connected with a first conductor that goes through the bottom in an airtight way and electrically connected with a second conductor that goes downward through the opening.

3. The waterproof structure in a tank of claim 2, wherein a plurality of electronic devices are disposed in the tank and the plurality of waterproof components are disposed on the outer sides of the electronic devices and the inner wall of the tank, and both ends of the second conductor electrically connect to the electronic elements in the waterproof components disposed on the outer sides of the electronic devices and the inner wall of the tank, respectively.

4. The waterproof structure in a tank of claim 3, wherein the surfaces of the first conductor and the second conductor are covered with an insulating material.

5. The waterproof structure in a tank of claim 3, wherein the electronic device includes a conductive platform or discharge aim, the second conductor electrically connect the electronic element on the inner wall of the tank and the conductive platform or discharge arm for transferring an external power to the conductive platform or discharge arm.

6. The waterproof structure in a tank of claim 5, wherein the conductive platform consists of a plurality of the insulating bases.

7. The waterproof structure in a tank of claim 3, wherein a circuit board is disposed on the outer wall of the tank corresponding to the electronic element, and the circuit board and the electronic element are in electrical connection through the wall of the tank.

8. The waterproof structure in a tank of claim 3, wherein each of the waterproof components further has a first soft pad and a second soft pad, with the cover, the soft pad, the bottom and the second soft pad stacked tightly in sequence.

9. The waterproof structure in a tank of claim 8, wherein a plurality of locking elements go through the cover, the first soft pad and the bottom to lock them.

10. The waterproof structure in a tank of claim 8, wherein the bottom and the second soft pad are locked to the inner wall of the tank or the outer wall of the electronic device using a plurality of locking elements.

11. The waterproof structure in a tank of claim 1, wherein a stop board is disposed by the waterproof component disposed adjacent to the inner wall of the tank.

12. The waterproof structure in a tank of claim 1, wherein the cover of the waterproof component is formed by bending a metal plate.

13. The waterproof structure in a tank of claim 1, wherein the cover is transparent for its user to observe from outside.

14. The waterproof structure in a tank of claim 1, wherein the cover or bottom is made of an insulating material selected from the group consisting of Bakelite, ceramics, engineering plastics, and glass.

15. The waterproof structure in a tank of claim 1, wherein the electronic element is an electrode contact.

16. The waterproof structure in a tank of claim 1, wherein the waterproof structure is used in a line cutter.
